(19) United States
(12) Patent Application Publication
(10) Pub. No.: US 2019/0010397 A1
(43) Pub. Date: Jan. 10, 2019

(54) LIQUID MIXTURE AND METHOD FOR ETCHING A SUBSTRATE USING THE LIQUID MIXTURE

(71) Applicant: Lam Research AG, Villach (AU)

(72) Inventor: Reinhard Sellmer, Villach (AT)

(21) Appl. No.: 15/642,951

(22) Filed: Jul. 6, 2017

(51) Int. Cl. C09K 13/06; H01L 45/00; C09K 13/08

(52) U.S. Cl. CPC C09K 13/06; H01L 45/085; C09K 13/08; H01L 45/146; H01L 45/1675; H01L 45/1233

(57) ABSTRACT

A liquid mixture for etching a substrate includes acetic acid in a range of 15 to 70 mass. % of the liquid mixture, nitric acid in a range of 5 to 50 mass. % of the liquid mixture, sulfuric acid in a range of 8 to 50 mass. % of the liquid mixture, and water in a range of 0 to 30 mass. % of the liquid mixture.

### FIELD

The present disclosure relates to substrate processing systems, and more particularly to a liquid mixture and methods for etching plasma-damaged and/or contaminated portions of a substrate using the liquid mixture.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems are used to deposit, etch and otherwise treat materials on substrates such as semiconductor wafers. Examples of etching processes include dry etching, vapor etching and/or wet etching. During processing, some layers of the substrate may be damaged by the plasma and/or contaminated by chemistry used in preceding process steps.

When one or more layers of the substrate are plasma-damaged and/or contaminated during processing, an etch process may be used to remove the plasma-damaged and/or contaminated portions of the substrate. The etch processes that are used to etch the plasma-damaged and/or contaminated portions are not sufficiently selective relative to other exposed materials of the substrate. In other words, when the etching process sufficiently etches the plasma-damaged and/or contaminated portions, it also etches a greater thickness of the other exposed materials than is desired.

### SUMMARY

A liquid mixture for etching a substrate includes acetic acid in a range of 15 to 70 mass. % of the liquid mixture; nitric acid in a range of 5 to 50 mass. % of the liquid mixture; sulfuric acid in a range of 8 to 50 mass. % of the liquid mixture; and water in a range of 0 to 30 mass. % of the liquid mixture.

In other features, the liquid mixture further comprises hydrofluoric acid in a range of 0.05 to 1 mass. % of the liquid mixture. The concentration of the hydrofluoric acid is in a range of 0.1 to 0.5 mass. % of the liquid mixture. The concentration of acetic acid is in a range of 20 to 60 mass. % of the liquid mixture. The concentration of nitric acid is in a range of 15 to 40 mass. % of the liquid mixture.

In other features, the concentration of sulfuric acid is in a range of 10 to 40 mass. % of the liquid mixture. The water comprises 0 to 20 mass. % of the liquid mixture.

A method for etching a substrate includes providing the substrate and dispensing the liquid mixture onto the substrate to etch the substrate.

In other features, the substrate includes a tantalum oxide layer. The liquid mixture etches a predetermined thickness of the tantalum oxide layer. The substrate comprises a resistive random access memory cell.

A method for etching a substrate includes arranging the substrate on a spin chuck, rotating the substrate using the spin chuck, and dispensing the liquid mixture onto the substrate to etch the substrate.

A method for etching a substrate includes providing the substrate, mixing the liquid mixture with hydrofluoric acid to create a second liquid mixture, and dispensing the second liquid mixture onto the substrate to etch the substrate.

In other features, the concentration of the hydrofluoric acid is in a range from 0.05 to 1 mass. % of the second liquid mixture. The concentration of the hydrofluoric acid is in a range from 0.1 to 0.5 mass. % of the second liquid mixture.

A method for wet etching a substrate includes arranging the substrate on a spin chuck, rotating the substrate using the spin chuck, mixing the liquid mixture of with hydrofluoric acid to create a second liquid mixture and dispensing the second liquid mixture onto the substrate to etch the substrate.

In other features, the concentration of the hydrofluoric acid is in a range from 0.05 to 1 mass. % of the second liquid mixture. The concentration of the hydrofluoric acid is in a range from 0.1 to 0.5 mass. % of the second liquid mixture.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A is a functional block diagram of an example of a spin chuck configured to apply a liquid mixture according to the present disclosure to selectively etch a substrate.

FIG. 1B is a plan view of the spin chuck of FIG. 1A.

FIG. 2 is a flowchart illustrating an example of a method for etching a substrate using the liquid mixture according to the present disclosure.

FIGS. 3A and 3B illustrate an example of a ReRAM memory cell.

In the drawings, reference numbers may be reused to identify similar and/or identical elements.

### DETAILED DESCRIPTION

The present disclosure relates to a liquid mixture for etching plasma-damaged and/or contaminated portions of a layer of a substrate. For example in some applications, an upper portion of a tantalum oxide layer is plasma-damaged and/or contaminated with a halogen species such as chlorine from one or more prior processing steps.

A liquid mixture of nitric acid (HNO₃) and hydrofluoric acid (HF) can be used to remove plasma-damaged or contaminated portions of the tantalum oxide layer. However, there are issues with controlling the etch rate and repeatability of the liquid mixture due to the formation of nitrous acid (HNO₂) during wet etching. Liquid mixtures without oxidizers or with different oxidizers, such as peroxide (H₂O₂) have shown insufficient removal of tantalum oxide. Mixtures without HF, such as aqua regia, have shown insufficient removal of tantalum oxide.

Removing the plasma-damaged and/or contaminated portions of the tantalum oxide layer during processing improves a data retention period during operation. Therefore it is desirable to remove the plasma-damaged and/or contaminated portions of the tantalum oxide layer while limiting damage and/or removal of other exposed materials of the substrate.

For example only, the other exposed materials may include a hardmask material (such as a chemical vapor deposition (CVD) hardmask oxide), tantalum pentoxide (Ta₂O₅), titanium nitride (TiN), electrode materials such as iridium (Ir), titanium nitride (TiN) or other materials. In some examples, the liquid mixture according to the present disclosure removes approximately 30 Angstroms (A) of the tantalum oxide while removing less than 200 or 180 Angstroms of CVD silicon oxide. In other words, etch selectivity of CVD oxide to tantalum oxide is limited in this example to less than approximately 7:1 or 6:1, respectively. In some examples, a spin chuck may be used to rotate the substrate while the liquid mixture is dispensed onto a surface of the substrate.

In some examples, the liquid mixture includes acetic acid, nitric acid, sulfuric acid, water and hydrofluoric acid. The acetic acid, nitric acid, and sulfuric acid can be pre-mixed and the hydrofluoric acid may be mixed with the liquid mixture by a blending system before dispensing the liquid mixture onto the spin chuck. Alternately, the acetic acid, nitric acid, sulfuric acid, and hydrofluoric acid can be pre-mixed.

In some examples, the liquid mixture includes acetic acid in a range of 15 to 70 mass. % of the liquid mixture, nitric acid in a range of 5 to 50 mass. % of the liquid mixture, sulfuric acid in a range of 8 to 50 mass. % of the liquid mixture, and water in a range of 0 to 30 mass. % of the liquid mixture. The concentration given in mass.-% are analytical concentrations.

In some examples, the liquid mixture further includes hydrofluoric acid. The hydrofluoric acid can be premixed or mixed with the liquid mixture prior to dispensing onto the substrate at the spin chuck. In some examples, the hydrofluoric acid is in a range of 0.05 to 1 mass. % of the liquid mixture. In other examples, the hydrofluoric acid is in a range of 0.1 to 0.5 mass. % of the liquid mixture.

In other examples, the acetic acid is in a range of 20 to 60 mass. % of the liquid mixture, the nitric acid is in a range of 15 to 40 mass. % of the liquid mixture, the sulfuric acid is in a range of 10 to 40 mass. % of the liquid mixture, and/or the water is in a range of 0 to 20 mass. % of the liquid mixture.

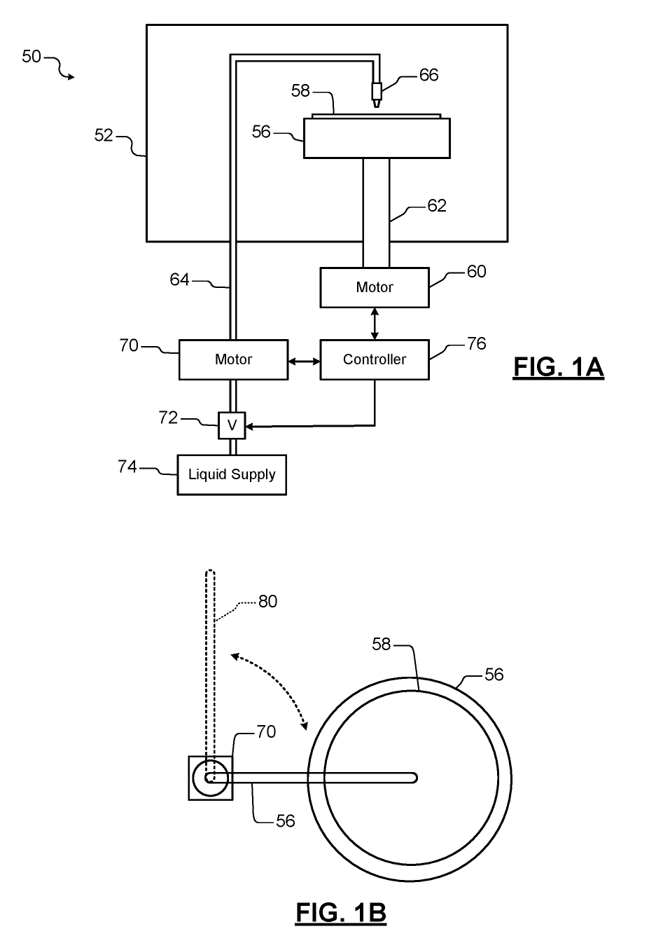

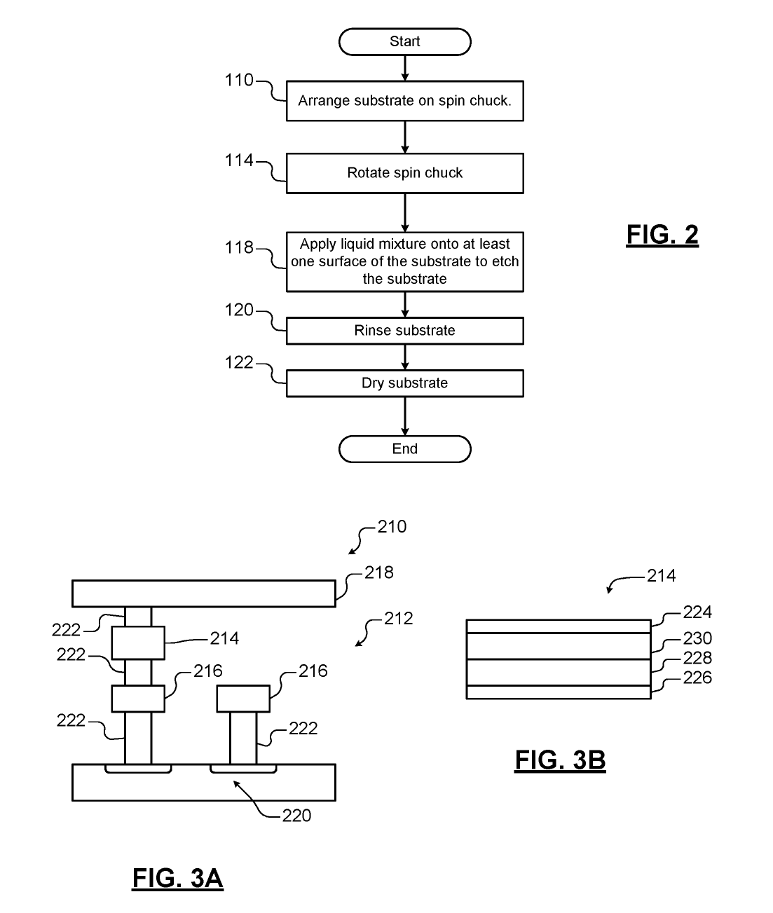

In the description below, an example of a spin chuck for dispensing the liquid mixture is shown in FIGS. 1A and 1B. An example of a method for using the liquid mixture is shown and described in FIG. 2. An example of a substrate including tantalum oxide that can be processed is shown in FIGS. 3A and 3B. While examples are shown, the liquid mixture can be used to etch other types of materials and/or other types of substrates. Additionally, the liquid mixture can be dispensed using other types of devices.

Referring now to FIGS. 1A and 1B, a spin chuck 50 is shown. The spin chuck 50 may be used to deliver the liquid mixture to selectively etch a portion of a layer that is plasma-damaged and/or contaminated while limiting removal of other materials. In FIG. 1A, the spin chuck 50 includes a processing chamber 52 and a rotatable chuck 56 supporting a substrate 58. A motor 60 rotates a shaft 62 connected to the rotatable chuck 56. A liquid delivery arm 64 and a nozzle 66 deliver liquid to a surface of the substrate 58 as the motor 60 rotates the shaft 62 connected to the rotatable chuck 56. A valve 72 controls delivery of one or more liquids such as deionized (DI) water, the liquid mixture described above and/or other liquids from a liquid supply 74. A controller 76 may be used to control the motor 60, a motor 70 and the valve 72 during etching. In FIG. 1B, a rotational position of the liquid delivery arm 64 may be adjusted from a dispensing position to a storage position shown in dotted lines using the motor 70. While a specific spin chuck is shown, other type of spin chucks or other ways of applying the liquid mixture can be used.

Referring now to FIG. 2, a method 100 for wet etching a substrate includes providing a substrate and arranging the substrate on a spin chuck at 110. In some examples, the substrate includes a plasma-damaged and/or contaminated material such as tantalum oxide and at least one other exposed material. The method includes rotating the substrate using the spin chuck at 114. At 118, the method includes applying the liquid mixture onto a surface of the substrate. The liquid mixture selectively etches the plasma-damaged and/or contaminated material such as tantalum oxide. In some examples, the substrate 58 is rinsed at 120 after etching using the liquid mixture with water (such as deionized water (DI) water). After rinsing, the substrate 58 may be dried at 122.

In some examples, the rotatable chuck 56 is rotated at a speed greater than or equal to 50 rpm. In other examples, the rotatable chuck 56 is rotated at a speed greater than or equal to 300 rpm. In other examples, the rotatable chuck 56 is rotated at a speed of 1000 rpm. In some examples, the liquid mixture is dispensed as a free flowing liquid onto the substrate 56. In some examples, the liquid mixture is dispensed at a temperature in a range from 10-40° C. (e.g. 25° C.).

In one example, the liquid mixture includes acetic acid at 54 mass. % of the liquid mixture, nitric acid at 19.8 mass. % of the liquid mixture, sulfuric acid at 15 mass. % of the liquid mixture, hydrofluoric acid at 0.2 mass. % of the liquid mixture and water at 11 mass. % of the liquid mixture.

In another example, the liquid mixture comprises acetic acid at 31.9 mass. % of the liquid mixture, nitric acid at 29 mass. % of the liquid mixture, sulfuric acid at 24 mass. % of the liquid mixture, hydrofluoric acid at 0.1 mass. % of the liquid mixture and water at 15 mass. % of the liquid mixture.

Referring now to FIGS. 3A and 3B, the liquid mixture described above may be used to etch a tantalum oxide layer of a resistive random access memory (ReRAM) cell 210. The ReRAM cell 210 includes a resistive element stack 214, a source line 216, a bit line 218, a switching transistor 220 and connections 222. The resistive element stack 214 may include a top electrode 224, a bottom electrode 226, a first layer 228 and a second layer 230. The first layer 228 includes tantalum oxide (TaO_{y}) and is arranged adjacent to the bottom electrode 226. A second layer 230 is arranged between the top electrode 224 and the first layer 228. The second layer 230 includes tantalum pentoxide (Ta₂O₅).

During operation, a first resistive state is set by applying a negative charge to the top electrode to cause migration of oxygen ions into the second layer 230. A second resistive state is set by applying a positive charge to the top electrode to cause migration of oxygen ions into the first layer 228. The first resistive state has a higher resistive value than the second resistive state.

During processing of the ReRAM cell 210, the first layer 228 and/or the second layer 230 are etched to remove plasma-damaged or contaminated portions. Removing the plasma-damaged and/or contaminated tantalum oxide during processing improves a data retention period of the ReRAM memory cell 210.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

1-7. (canceled)

8. A method for etching a substrate, comprising:
providing the substrate, wherein the substrate comprises a first exposed material and a second exposed material, wherein the first exposed material comprises tantalum oxide, and wherein the second exposed material is different than the first exposed material;
treating the substrate using a plasma or a halogen species during processing, wherein a portion of the first exposed material is plasma-damaged or contaminated by the halogen species; and
dispensing a liquid mixture onto the substrate to etch the plasma-damaged or contaminated portion of the first exposed material and a portion of the second exposed material from the substrate,
wherein the liquid mixture includes
acetic acid in a range of 15 to 70 mass. % of the liquid mixture;
nitric acid in a range of 5 to 50 mass. % of the liquid mixture;
sulfuric acid in a range of 8 to 50 mass. % of the liquid mixture; and
water in a range of 0 to 30 mass. % of the liquid mixture.

9. (canceled)

10. The method of claim 8, wherein the substrate comprises a resistive random access memory cell.

11. The method of claim 8, further comprising prior to dispensing the liquid mixture:
arranging the substrate on a spin chuck; and
rotating the substrate using the spin chuck.

12. The method of claim 8 further comprising mixing the liquid mixture with hydrofluoric acid prior to dispensing the liquid mixture.

13. The method of claim 12, wherein the concentration of the hydrofluoric acid is in a range from 0.05 to 1 mass. % of the liquid mixture.

14. The method of claim 12, wherein the concentration of the hydrofluoric acid is in a range from 0.1 to 0.5 mass. % of the liquid mixture.

15. The method of claim 11 further comprising prior to dispensing the liquid mixture, mixing the liquid mixture with hydrofluoric acid.

16. The method of claim 15, wherein the concentration of the hydrofluoric acid is in a range from 0.05 to 1 mass. % of the liquid mixture.

17. The method of claim 16, wherein the concentration of the hydrofluoric acid is in a range from 0.1 to 0.5 mass. % of the liquid mixture.

18. The method of claim 8, wherein the concentration of acetic acid is in a range of 20 to 60 mass. % of the liquid mixture.

19. The method of claim 8, wherein the concentration of nitric acid is in a range of 15 to 40 mass. % of the liquid mixture.

20. The method of claim 8, wherein the concentration of sulfuric acid is in a range of 10 to 40 mass. % of the liquid mixture.

21. The method of claim 8, wherein the water comprises 0 to 20 mass. % of the liquid mixture.

22. The method of claim 8, wherein more of the second exposed material is removed than the first exposed material due to the dispensing of the liquid mixture.

23. The method of claim 8, wherein a thickness of the portion of the second exposed material, which is etched, is thicker than a thickness of the plasma-damaged or contaminated portion that is etched.

24. The method of claim 8, wherein an etch selectivity ratio of the second exposed material relative to the first exposed material is less than 7:1.

25. The method of claim 8, wherein an etch selectivity ratio of the second exposed material relative to the first exposed material is less than 6:1.

26. The method of claim 8, wherein the second exposed material comprises a chemical vapor deposition hardmask oxide.

27. The method of claim 8, wherein the second exposed material comprises titanium nitride.

28. The method of claim 8, wherein the second exposed material comprises iridium.

29. The method of claim 8, wherein the second exposed material comprises tantalum pentoxide.

30. The method of claim 8, further comprising limiting an amount of the second exposed material that is etched from the substrate while dispensing the liquid mixture onto the substrate to etch the plasma-damaged or contaminated portion of the first exposed material.
